(19) United States
(12) Patent Application Publication
(10) Pub. No.: US 2021/0267093 A1
(43) Pub. Date: Aug. 26, 2021

(54) Heat Sink Fin Having An Integrated Airflow Guiding Structure For Redirecting Airflow

(71) Applicant: DELL PRODUCTS L.P., Round Rock, TX (US)

(72) Inventors: Yu-Ming Kuo, New Taipei City (TW); Ching-Hsiang Yang, Taichung City (TW)

(21) Appl. No.: 16/800,704

(22) Filed: Feb. 25, 2020

(51) Int. Cl. H05K 7/20; G06F 1/20

(52) U.S. Cl. CPC H05K 7/20418; H05K 7/20918; G06F 1/20

(57) ABSTRACT

Cooling system components are provided herein to direct airflow within an information handling system. More specifically, various embodiments of fin structures are provided herein to direct airflow in at least two different directions. In one embodiment, the fin structure includes a plurality of fins arranged parallel to one another, where at least one integrated airflow guiding structure is formed within each of the plurality of fins. The plurality of fins function to dissipate thermal energy, which is generated by a heat generating component and conducted by a heat sink to the fin structure via convection. As air flows through the plurality of fins in a primary airflow direction, the at least one integrated airflow guiding structure redirects a portion of the airflow in a direction, which differs from the primary airflow direction.

### FIELD

This invention relates generally to cooling system components for information handling systems (IHSs), and more particularly, to cooling system components configured to direct airflow within an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems (IHSs) typically use some form of active and/or passive thermal management to direct heat away from heat generating components contained within the IHS. For example, one or more fans may be included within a chassis or housing of an IHS to provide active cooling to one or more heat generating components (e.g., CPUs, GPUs, voltage regulators, SSDs, chipsets, and/or memory modules) contained therein. In another example, heat generating components may be thermally coupled to a thermoelectric cooler (TEC) and/or a heat sink (e.g., a heat exchanger, metal chassis or other thermally conductive component within the IHS), which passively draws heat away from the heat generating components. In some cases, a heat pipe may be coupled to one or more heat generating components for directing heat away to a heat sink, or another active or passive cooling component, contained within the IHS.

Heat sinks are an essential part of the IHS thermal management solution, and are typically designed to ensure that the heat generating components included within the IHS can operate within the thermal design limits specified by manufacturers. Most IHSs include one or more heat sinks positioned on (or near) one or more heat generating components of the IHS to dissipate heat generated by the heat generating component(s). For example, a heat sink is typically mounted to a central processing unit (CPU) or chipset to provide thermal management for the CPU. In some cases, one or more additional heat sinks may be arranged on the system motherboard to provide passive cooling for other IHS components.

Heat sinks are passive heat exchangers, which are formed from thermally conductive materials (e.g., copper, aluminum, etc.) and used to transfer thermal energy generated by a heat generating component to a cooling medium or fluid (such as air). Heat sinks passively dissipate heat generated by heat generating component(s) by transferring thermal energy from a higher temperature region to a lower temperature region via conduction, convection (e.g., natural or forced convection), radiation or a combination of heat transfer methods. In some cases, fins may be added to the heat sink to increase the surface area of the heat sink, improve thermal dissipation and direct airflow.

Most heat sinks contained within an IHS are designed to maximize heat transfer away from major heat generating components of the IHS (such as the CPU or chipset). Key factors that should be considered in heat sink design include thermal resistance and material, as well as fin configuration, shape and size. For example, optimizing the fin configuration helps to reduce fluid flow resistance across the heat sink (thus allowing more air to pass through), while optimizing the shape and size of the fins helps to maximize the heat transfer density. Fin configuration, shape and size, and other heat sink parameters that provide maximum heat dissipation, are typically obtained by analyzing different heat sink models before finalizing the heat sink design for a particular IHS or system motherboard layout.

Unfortunately, thermal characteristics of information handling systems are dynamic, and can change when operating currents are supplied to various heat generating components change. For example, a voltage regulator (VR) is often mounted to the system motherboard near the CPU to regulate the voltage supplied to the CPU. With each new CPU generation, the operating current supplied to the VR increases, thereby increasing the amount of heat generated by the VR. Although the VR is positioned near the CPU and the CPU cooling system components, the air from the cooling system components typically flows above the VR to provide only a negligible amount of heat dissipation. When VR thermal characteristics become a problem, system designers are often forced to add an additional heat sink to the voltage regulator, redesign the CPU heat sink (e.g., by changing the vertical or horizontal dimensions of the heat sink fins), or include a separate baffle within the IHS to redirect airflow from the CPU cooling system to the VR. However, these solutions increase costs and consume valuable space within the system.

### SUMMARY OF THE INVENTION

The following description of various embodiments of fin structures, information handling systems and methods is not to be construed in any way as limiting the subject matter of the appended claims.

According to various embodiments of the present disclosure, cooling system components are provided herein to direct airflow within an information handling system. More specifically, the present disclosure provides various embodiments of fin structures configured to direct airflow in at least two different directions. In each embodiment, the fin structure includes a plurality of fins, and each fin includes an integrated airflow guiding structure for redirecting at least a portion of the air flowing through the plurality of fins. In the disclosed embodiments, the integrated airflow guiding structure is implemented as a baffle, or a divider. It is noted, however, that other implementations or configurations of integrated airflow guiding structures may also be used to redirect airflow through the plurality of fins.

According to one embodiment, a fin structure provided herein may generally include a plurality of fins arranged parallel to one another, where at least one structure (i.e., an integrated airflow guiding structure) is integrated within each of the plurality of fins. The plurality of fins may be configured to dissipate thermal energy, which is generated by a heat generating component and conducted by a heat sink to the fin structure via convection. As air flows through the plurality of fins in a primary airflow direction, the at least one integrated airflow guiding structure may redirect a portion of the airflow in a direction, which differs from the primary airflow direction.

In some embodiments, the plurality of fins may be stacked together to form a stacked fin structure, which can be thermally coupled to the heat sink. In other embodiments, the fin structure may be implemented as one integral piece and/or may be integrated with the heat sink.

In general, the at least one integrated airflow guiding structure may formed anywhere along an egress side of each of the plurality of fins where the airflow exits the fin structure. In some embodiments, the at least one integrated airflow guiding structure may be formed within a lower portion of each of the plurality of fins on the egress side. In some embodiments, the at least one integrated airflow guiding structure may be formed by cutting a substantially rectangular shaped tab within each of the plurality of fins on the egress side, and bending the tab inward.

In one embodiment, the substantially rectangular shaped tab may be formed within each of the plurality of fins at an angle approximately −75° to 75° from the primary airflow direction. In such an embodiment, the substantially rectangular shaped tab may be bent inward to form a baffle within each fin. As air flows through the plurality of fins in a primary airflow direction, the baffle may capture a portion of the airflow and redirect the captured portion in a substantially downward direction toward one or more heat generating components arranged within a vicinity of the heat generating component.

In another embodiment, the substantially rectangular shaped tab may be formed substantially parallel to the egress side of each of the plurality of fins. In such an embodiment, the substantially rectangular shaped tab may be bent inward to form a divider within each fin, which is substantially perpendicular to the primary airflow direction. As air flows through the plurality of fins in the primary airflow direction, the divider may divide the airflow between the primary airflow direction and a secondary airflow direction, which provides a cooling effect to one or more heat generating components arranged within a vicinity of the heat generating component.

According to another embodiment, an information handling system provided herein may generally include a heat generating component, a heat sink thermally coupled to the heat generating component for conducting heat generated by the heat generating component, and a fin structure thermally coupled to the heat sink for dissipating the heat conducted by the heat sink via convection or radiation into a lower temperature region surrounding the heat generating component. In some embodiments, the information handling system may also include one or more active cooling components, which are coupled to (or mounted near) the heat sink and fin structure to increase airflow velocity through the fin structure and improve heat dissipation.

In general, the fin structure may include a plurality of fins arranged parallel to one another, where at least one structure (i.e., an integrated airflow guiding structure) is integrated within each of the plurality of fins. The at least one integrated airflow guiding structure may be formed anywhere along an egress side of each of the plurality of fins where the airflow exits the fin structure. In some embodiments, the at least one integrated airflow guiding structure may be formed within a lower portion of each of the plurality of fins on the egress side. As air flows through the plurality of fins in a primary airflow direction, the at least one integrated airflow guiding structure may redirect a portion of the airflow in a direction, which differs from the primary airflow direction.

In some embodiments, the at least one integrated airflow guiding structure may be formed by cutting a substantially rectangular shaped tab within each of the plurality of fins on the egress side, and bending the tab inward to form a baffle or a divider within each fin.

In one embodiment, the substantially rectangular shaped tab may be formed within each of the plurality of fins at an angle approximately −75° to 75° from the primary airflow direction. In such an embodiment, the substantially rectangular shaped tab may be bent inward to form a baffle within each fin. As air flows through the plurality of fins in a primary airflow direction, the baffle may capture a portion of the airflow and redirect the captured portion in a substantially downward direction toward one or more heat generating components arranged within a vicinity of the heat generating component.

In another embodiment, the substantially rectangular shaped tab may be formed substantially parallel to the egress side of each of the plurality of fins. In such an embodiment, the substantially rectangular shaped tab may be bent inward to form a divider within each fin, which is substantially perpendicular to the primary airflow direction. As air flows through the plurality of fins in the primary airflow direction, the divider may divide the airflow between the primary airflow direction and a secondary airflow direction, which provides a cooling effect to one or more heat generating components arranged within a vicinity of the heat generating component.

According to another embodiment, a method is provided herein to form a stacked fin structure including a plurality of fins. In general, the method may include forming a substantially rectangular shaped tab within an egress side of each of the plurality of fins, bending the substantially rectangular shaped tab inward to create an integrated air guiding structure on the egress side of each fin, stacking the plurality of fins together, and coupling a first fin and a last fin to opposing sides of the stacked plurality of fins to complete the stacked fin structure.

Once completed, the stacked fin structure may be used to dissipate thermal energy via airflow through the plurality of fins in a primary airflow direction, and the integrated airflow guiding structure may redirect a portion of the airflow in a direction, which differs from the primary airflow direction. To prevent air from leaking from the sides of the stacked fin structure, the first fin and the last fin may be formed without an integrated air guiding structure.

In some embodiments, said forming may include forming the substantially rectangular shaped tab at an angle approximately −75° to 75° from the primary airflow direction. In such embodiments, said bending may include bending the substantially rectangular shaped tab inward to form a baffle within each fin. When the stacked fin structure is used to dissipate thermal energy, the baffle created within each fin is configured to capture a portion of the airflow and redirect the captured portion in a substantially downward direction.

In other embodiments, said forming may include forming the substantially rectangular shaped tab substantially parallel to the egress side of each of the plurality of fins. In such embodiments, said bending may include bending the substantially rectangular shaped tab inward to form a divider within each fin, which is substantially perpendicular to the primary airflow direction. When the stacked fin structure is used to dissipate thermal energy, the divider created within each fin is configured to divide the airflow between the primary airflow direction and a secondary airflow direction, which provides a cooling effect to one or more heat generating components arranged within a vicinity of the heat generating component.

### BRIEF DESCRIPTION OF THE DRAWINGS

Other advantages of the present disclosure will become apparent upon reading the following detailed description and upon reference to the accompanying drawings in which:

FIG. 1 is a block diagram illustrating one embodiment of an information handling system (IHS) including a plurality of heat generating components and at least one passive cooling system comprising a heat sink and fin structure configured to direct airflow in multiple directions;

FIG. 2A is a side perspective view illustrating one embodiment of a fin structure having an integrated airflow guiding structure, in accordance with the present disclosure;

FIG. 2B is a cross-sectional view through the fin structure shown in FIG. 2A, illustrating how the integrated airflow guiding structure redirects a portion of the airflow through the fin structure to one or more heat generating components, which are mounted to a printed circuit board (PCB) in the vicinity of a host processor;

FIGS. 3A-3D are side and side perspective views illustrating one embodiment of a method that may be used to form the fin structure shown in FIG. 2A;

FIG. 4A is a perspective view illustrating another embodiment of a fin structure having an integrated airflow guiding structure, in accordance with the present disclosure;

FIG. 4B is cross-sectional view through the fin structure shown in FIG. 4A, illustrating how the integrated airflow guiding structure redirects a portion of the airflow through the fin structure to one or more heat generating components, which are mounted to a PCB in the vicinity of a host processor; and

FIGS. 5A-5D are side and side perspective views illustrating one embodiment of a method that may be used to form the fin structure shown in FIG. 4A.

While the present disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form disclosed, but on the contrary, the present disclosure is to cover all modifications, equivalents and alternatives falling within the spirit and scope of the present disclosure as defined by the appended claims.

### DESCRIPTION OF ILLUSTRATIVE EMBODIMENTS

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may generally include random access memory (RAM), one or more processing resources such as a central processing unit (CPU) or hardware or software control logic, read only memory (ROM), and/or other types of nonvolatile memory. Additional components of the information handling system may include one or more disk drives, one or more network ports for communicating with external devices as well as various input and output (I/O) devices, such as a keyboard, a mouse, touch screen and/or a video display. The information handling system may also include one or more buses operable to transmit communications between the various hardware components.

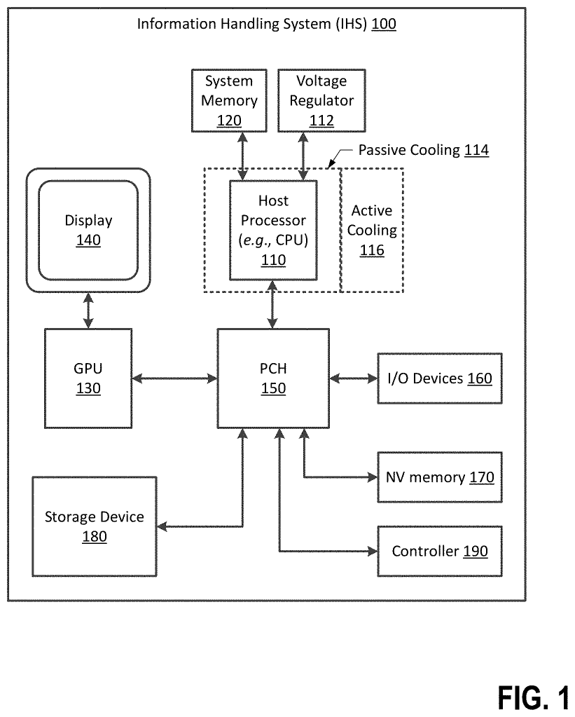

FIG. 1 illustrates one embodiment of an information handling system 100 (e.g., a desktop computer, laptop computer, server, Internet of Things (IoT) device, etc.) that may use embodiments of the fin structure disclosed herein to improve thermal management for one or more heat generating components contained within the IHS. As shown in FIG. 1, IHS 100 may generally include at least one host processor 110 (e.g., a central processing unit, CPU), voltage regulator (VR) 112, system memory 120, graphics processor unit (GPU) 130, display device 140, platform controller hub (PCH) 150, input/output (I/O) devices 160, expansion buses 162, computer readable non-volatile (NV) memory 170, computer readable storage device 180, and controller 190.

In the embodiment shown in FIG. 1, one or more cooling system components are included within IHS 100 to provide passive and/or active cooling for the heat generating components contained therein. Examples of heat generating components contained within IHS 100 include, but are not limited to, CPU 110, VR 112, system memory 120, GPU 130, PCH 150, computer readable NV memory 170, and computer readable storage device 180. As described in more detail below, the one or more cooling system components may include at least one heat sink and fin structure, which is configured to direct airflow in multiple directions. In some embodiments, HIS 100 may include one or more additional cooling system components, including passive cooling components (such as a thermoelectric cooler, TEC, additional heat sinks and/or heat pipes) and/or active cooling components (such as fans).

It is expressly noted that the IHS configuration shown in FIG. 1 is exemplary only, and that the fin structures disclosed herein may be implemented within any type and/or configuration of information handling system having a plurality of heat generating components and one or more cooling system components for passively and/or actively cooling the heat generating components contained within the IHS. It will be further understood that while certain IHS components are shown in FIG. 1 for illustrating embodiments of the present disclosure, the IHS disclosed herein is not restricted to including only those components shown in FIG. 1 and described below.

Returning to FIG. 1, host processor 110 may be generally configured to execute program instructions (or computer program code) for the IHS, and may include various types of programmable integrated circuits (e.g., a processor such as a controller, microcontroller, microprocessor, ASIC, etc.) and programmable logic devices (such as a field programmable gate array “FPGA”, complex programmable logic device “CPLD”, etc.). According to one embodiment, host processor 110 may include at least one central processing unit (CPU) having one or more processing cores. The CPU may include any type of processing device, such as an Intel Pentium series processor, an Advanced Micro Devices (AMD) processor or another processing device.

Voltage regulator 112 is coupled to host processor 110 and configured to adjust and regulate the operating voltage applied to the host processor. In some embodiments, voltage regulator 112 may be positioned on a system motherboard near the host processor 110. During operation of the IHS 100, an operating current supplied to voltage regulator 112 may be changed to support faster or slower processing speeds. For example, the operating current supplied to voltage regulator 112 may be increased to increase the operating voltage needed for host processor 110 to support faster processing speeds. Unfortunately, increases in operating currents/voltages tend to increase the amount of heat generated by host processor 110 and voltage regulator 112, and in some cases, may cause the host processor or voltage regulator to exceed thermal design limits.

System memory 120 is coupled to host processor 110 and generally configured to store program instructions (or computer program code), which are executable by host processor 110. System memory 120 may be implemented using any suitable memory technology, including but not limited to, random access memory (RAM), static RAM (SRAM), dynamic RAM (DRAM), synchronous dynamic RAM (SDRAM), non-volatile RAM (NVRAM), erasable programmable ROM (EPROM), electrically erasable programmable ROM (EEPROM), Flash memory, or any other type of volatile memory.

Graphics processor unit (GPU) 130 is coupled to host processor 110 and configured to coordinate communication between the host processor and one or more display components of the IHS. In the embodiment shown in FIG. 1, GPU 130 is coupled to display device 140 and configured to provide visual images to the user. Although GPU 130 is shown as a separate processing device in the embodiment of FIG. 1, GPU 130 may be omitted in other embodiments, when the functionality provided thereby is integrated within host processor 110 in a system-on-chip (SoC) design. In some embodiments, IHS 100 may include other types of processing devices including, but not limited to, a graphics-derivative processor (such as a physics/gaming processor), a digital signal processor (DSP), etc.

Platform controller hub (PCH) 150 is coupled to host processor 110 and configured to handle I/O operations for the IHS. As such, PCH 150 may include a variety of communication interfaces and ports for communicating with various system components, such as input/output (I/O) devices 160, computer readable NV memory 170, computer readable storage device 180, and controller 190.

I/O devices 160 enable the user to interact with IHS 100, and to interact with software/firmware executing thereon. In some embodiments, one or more I/O devices 160 may be present within, or coupled to, IHS 100. In some embodiments, I/O device(s) 160 may be separate from the IHS and may interact with the IHS through a wired or wireless connection. Examples of I/O devices 160 include, but are not limited to, keyboards, keypads, touch screens, mice, scanning devices, voice or optical recognition devices, and any other devices suitable for entering or retrieving data.

Computer readable memory 170 may include any type of non-volatile (NV) memory including, but not limited to, read-only memory (ROM), Flash memory (e.g., SPI Flash memory) and non-volatile random-access memory (NVRAM), and may be generally configured to store software and/or firmware modules. The software and/or firmware modules stored within computer readable NV memory 170 may generally contain program instructions (or computer program code), which may be executed by host processor 110 (and/or other controllers included within the IHS) to instruct components of IHS 100 to perform various tasks and functions for the information handling system.

Computer readable storage device 180 is coupled to PCH 150, and is generally configured to store software and/or data. For example, computer readable storage device 180 may be configured to store an operating system (OS) for the IHS, in addition to other software and/or firmware modules and user data. Computer readable storage device 180 may include any type of persistent, non-transitory computer readable storage medium, such as one or more hard disk drives (HDDs), optical drives, solid-state drives (SSDs) and/or any other suitable form of non-transitory computer readable storage media.

Controller 190, which is coupled to PCH 150, may comprise hardware, software and/or firmware. In some embodiments, controller 190 may be an embedded controller (EC) or a dedicated microcontroller provided, for example, on a trusted platform of the IHS. Controller 190 is configured to execute program instructions (or computer program code), which may be stored within system memory 120 and/or storage device 180.

During operation of IHS 100, heat generated by various heat generating components, such as CPU 110, VR 112, system memory 120, GPU 130, PCH 150, computer readable NV memory 170, and computer readable storage device 180, may cause one or more of the heat generating components to exceed thermal design limits specified by manufacturers for these components. To avoid over-heating, at least one of the heat generating components (e.g., CPU 110, GPU 130, PCH 150 and/or storage device 180) contained within IHS 100 may be thermally coupled to an active or passive heat sink, heat exchanger, heat spreader and/or active cooling unit. As known in the art, a passive heat sink may include fins or other protrusions for dissipating heat, while an active heat sink comprises (or is coupled to) an active cooling unit, such as a fan, to provide convective cooling to the heat sink. In some embodiments, one or more of the heat generating components may be thermally coupled to one or more heat pipes for conducting heat generated by the component(s) to an active or passive heat sink.

In conventional systems, passive and active cooling components are often coupled to the host processor to dissipate heat generated by the host processor. These cooling system components are generally designed to meet the thermal design limits specified by the manufacturer for the host processor. In some cases, additional cooling components may be included within conventional systems to provide cooling to other system components. Unfortunately, the cooling system components included within conventional systems may not provide adequate cooling to the host processor and/or other system components at all times, such as when operating parameters change.

As noted above, a voltage regulator (VR) is typically mounted on the system motherboard near the host processor (e.g., CPU) for adjusting and regulating the operating voltage applied to the host processor. When an operating current supplied to the voltage regulator is increased to support greater processing speeds, the amount of heat generated by the VR and the CPU both increase. Even though the VR is arranged near the CPU and the CPU cooling system components, air from the CPU cooling system components typically flows above the VR to provide only a negligible amount of heat dissipation. When VR thermal characteristics become a problem, system designers are often forced to add an additional heat sink to the VR, redesign the CPU heat sink (e.g., by changing the vertical or horizontal dimensions of the heat sink fins), or include a separate baffle within the system to redirect airflow from the CPU cooling system components to the VR. However, these solutions increase costs and consume valuable space within the system.

In the embodiment shown in FIG. 1, one or more passive cooling components 114 are coupled to host processor 110 for dissipating heat generated by the host processor. As described in more detail below, passive cooling components 114 may generally include a heat sink and fin structure. The heat sink, which is mounted onto and thermally coupled to host processor 110, conducts thermal energy (heat) to the fin structure, which dissipates the thermal energy via convection (e.g., natural or forced convection) or radiation into a lower temperature region surrounding the host processor. Unlike conventional systems, the fin structure disclosed herein is designed to direct airflow in multiple directions, so as to improve thermal characteristics of host processor 110 and surrounding heat generating components (such as, e.g., VR 112, system memory 120, GPU 130, PCH 150 and/or computer readable storage device 180). In some embodiments, one or more active cooling components 116 (such as a fan) may be coupled to (or mounted near) the heat sink and fin structure disclosed herein to increase airflow velocity through the fin structure and improve heat dissipation.

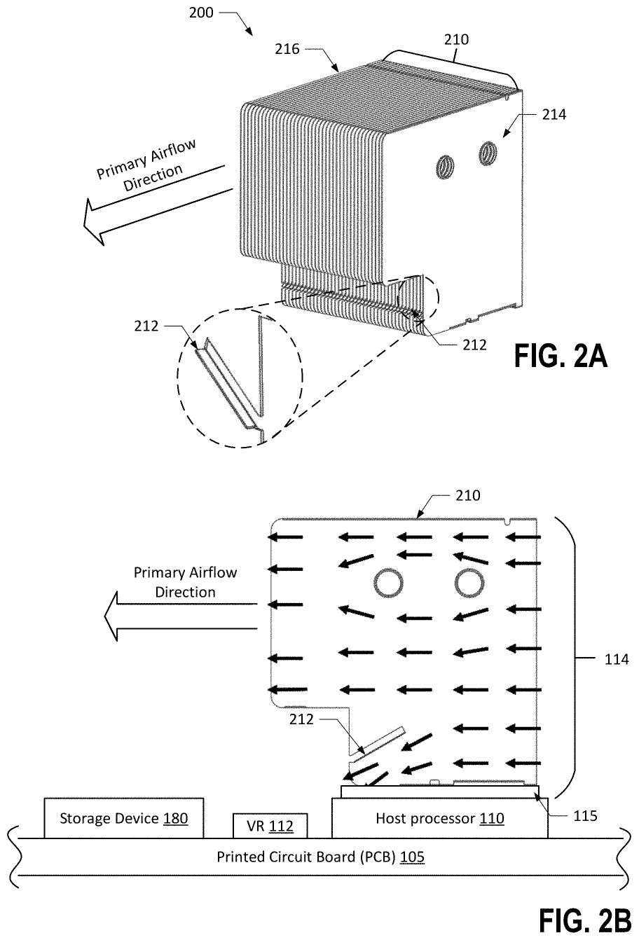

FIGS. 2-5 illustrate various embodiments of a fin structure in accordance with the present disclosure. In the illustrated embodiments, the fin structure is implemented as a stacked fin structure. In some embodiments, the stacked fin structure may be thermally coupled to a heat sink for dissipating thermal energy (or heat), which is generated by a heat generating component and conducted by the heat sink to the stacked fin structure. However, the fin structure disclosed herein is not strictly limited to a stacked fin structure, and may be alternatively implemented in other embodiments. In some embodiments, the fin structure may be implemented as one integral piece and/or may be integrated with a heat sink.

FIGS. 2A-2B illustrate one embodiment of a fin structure 200 having a plurality of fins. A side perspective view of the completed fin structure 200 is shown in FIG. 2A. In FIG. 2B, a single fin within fin structure 200 is shown mounted onto a heat sink 115, which is thermally coupled to a host processor 110 mounted onto a printed circuit board (PCB) 105 (such as a system motherboard). As described in more detail below, a majority of the fins within fin structure 200 include at least one integrated airflow guiding structure for redirecting a portion of the air flowing through the fin structure to one or more heat generating components, which are mounted onto the PCB 105 in the vicinity of the host processor 110. In some embodiments, an active cooling component 116 (such as a fan) may be coupled to (or mounted near) the heat sink 115 and fin structure 200 to increase airflow velocity through the fin structure and improve heat dissipation.

As shown in FIG. 2A, fin structure 200 includes a plurality of fins, which are arranged parallel to one another and stacked together to form a stacked fin structure. A majority of the fins 210 include an integrated airflow guiding structure 212, which is formed on an egress side of the fin structure 200 where airflow exits the fin structure. To complete the fin structure 200, a first fin 214 and a last fin 216 are coupled to the sides of the stacked fins 210. To prevent airflow from leaking from the sides of the fin structure 200, an integrated airflow guiding structure 212 is not formed within the first and last fin 214, 216.

In the embodiment shown in FIGS. 2A-2B, the integrated airflow guiding structure 212 is formed within a lower portion of each fin 210 on the egress side of the fin. In some embodiments, the lower portion of the fins 210 may be narrower than an upper portion of the fins 210 to avoid interference with nearby system components. It is noted, however, that the fin geometry is not strictly limited to the particular configuration shown in FIG. 2A and may be alternatively configured in other embodiments. In some embodiments, for example, the upper and lower portions may have substantially uniform width, and the lower portion may simply be defined as residing within a lower half of the fins 210.

In some embodiments, the integrated airflow guiding structure 212 may be created by forming a substantially rectangular shaped tab 211 within the lower portion of each fin 210 on the egress side, and bending the tab inward approximately 90° to form a baffle within each fin 210. In some embodiments, the substantially rectangular shaped tab 211 created within each fin 210 may be formed at an angle approximately −75° to 75° from the primary airflow direction. The length and width of the integrated airflow guiding structure 212 (or baffle) may generally be chosen based on fin configuration, fin spacing and thermal design needs.

In some embodiments, the length of the integrated airflow guiding structure 212 may be generally dependent on the angle at which the substantially rectangular shaped tab 211 is formed within the plurality of fins 210. For example, a longer length may be required to redirect airflow when the substantially rectangular shaped tab 211 is formed at a shallower angle (and vice versa). In some embodiments, the width of the integrated airflow guiding structure 212 may be generally dependent on the spacing or pitch between the fins 210. In one embodiment, integrated airflow guiding structure 212 may have a length ranging between about 7.5 mm and about 8.5 mm, and a width ranging between about 0.6 mm and about 0.8 mm. Other dimensions may be used in fin structures having alternative fin geometry and/or spacing.

Although examples are provided herein for illustrative purposes, the dimensions of the integrated airflow guiding structure 212, as well as the placement of the structure along the egress side of the fins 210, are not so strictly limited. Instead, the dimensions and placement of the integrated airflow guiding structure 212 may be chosen to redirect airflow, as needed, to meet thermal design limits specified for the host processor 110 and/or nearby heat generating component(s).

As air flows through the fin structure 200, the integrated airflow guiding structure 212 (or baffle) captures a portion of the airflow and redirects the captured portion in a direction, which differs from the primary airflow direction. In the embodiment shown in FIGS. 2A-2B, the integrated airflow guiding structure 212 (or baffle) redirects the captured portion of the airflow in a substantially downward direction to provide a cooling effect to one or more heat generating components, which are mounted to PCB 105 in the vicinity of the host processor 110.

VR 112 and computer readable storage device 180 are illustrated in FIG. 2B as examples of heat generating components that benefit from the cooling effect provided by fin structure. However, fin structure 200 is not limited to cooling any particular component, and may be alternatively used to redirect airflow and provide a cooling effect to other heat generating components arranged within the vicinity of host processor 110. In some embodiments, an active cooling component 116 (such as a fan) may be coupled to (or mounted near) an ingress side of fin structure 200 to increase airflow velocity through the fin structure, improve heat dissipation away from host processor 110 and improve thermal characteristics of nearby heat generating components.

It is noted that FIGS. 2A-2B illustrate only one possible embodiment of a fin structure 200 having an integrated airflow guiding structure 212 in accordance with the present disclosure. Although implemented on a lower portion of the fin structure 200 in FIGS. 2A-2B, the integrated airflow guiding structure 212 is not strictly limited to such, and may be alternatively positioned anywhere along the egress side of fin structure 200. In some embodiments, a plurality of integrated airflow guiding structures 212 may be formed along the egress side of fin structure 200 to redirect airflow in multiple directions.

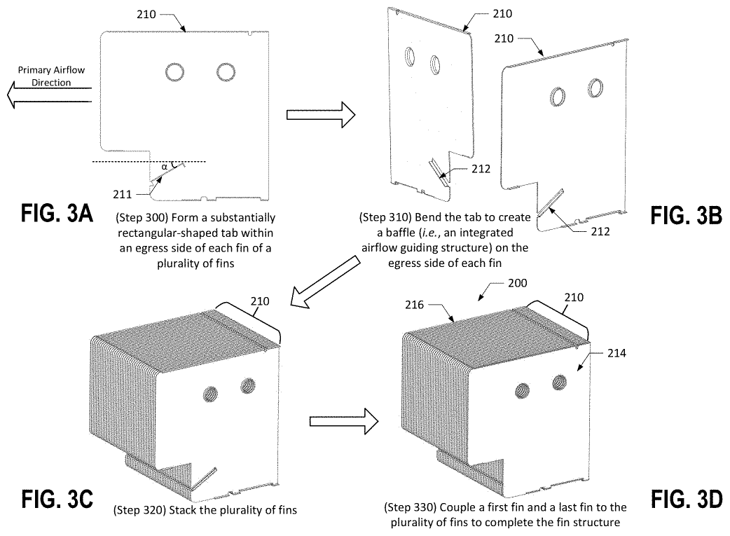

FIGS. 3A-3D illustrate one embodiment of a method that may be used to form the fin structure 200 shown in FIG. 2A. As noted above, fin structure 200 includes a plurality of fins, which are stacked together to form a stacked fin structure. In some embodiments, the method may begin (in step 300) by forming a substantially rectangular shaped tab 211 within an egress side of each individual fin 210. In the embodiment shown in FIG. 3A, a substantially rectangular shaped tab 211 is formed (e.g., cut) within a lower portion of each fin 210, on the egress side of the fin. In other embodiments, the substantially rectangular shaped tab 211 may be formed anywhere along the egress side of the fin 210, as discussed above.

In order to redirect airflow in a desired direction, the substantially rectangular shaped tab 211 may be formed at an angle (a) approximately −75° to 75° from the primary airflow direction. As noted above, the length of the substantially rectangular shaped tab 211 may be generally dependent on the angle (a), and the width may depend on the spacing or pitch between fins 210. In one embodiment, the substantially rectangular shaped tab 211 may have a length ranging between about 7.5 mm and about 8.5 mm, and a width ranging between about 0.6 mm and about 0.8 mm. However, the length and width of the substantially rectangular shaped tab 211 is not restricted to the example ranges provided herein, and may generally be chosen based on fin configuration, fin spacing and thermal design needs.

In step 310, the substantially rectangular shaped tab 211 is bent to create an integrated air guiding structure (or baffle) 212 on the egress side of each fin 210. In some embodiments, the substantially rectangular shaped tab 211 may be bent inward approximately 90° to form an integrated airflow guiding structure (or baffle) 212 within each fin 210, as shown in FIG. 3B. Once an integrated airflow guiding structure (or baffle) 212 is formed within each fin 210, the plurality of fins 210 may be stacked together (in step 320), as shown in FIG. 3C. In step 330, a first fin 214 and a last fin 216 are coupled to opposing sides of the stacked plurality of fins 210 to complete the fin structure 200, as shown in FIG. 3D. As noted above, the first and last fins 214, 216 are preferably formed without an integrated airflow guiding structure 212 to prevent airflow from leaking from the sides of the fin structure 200.

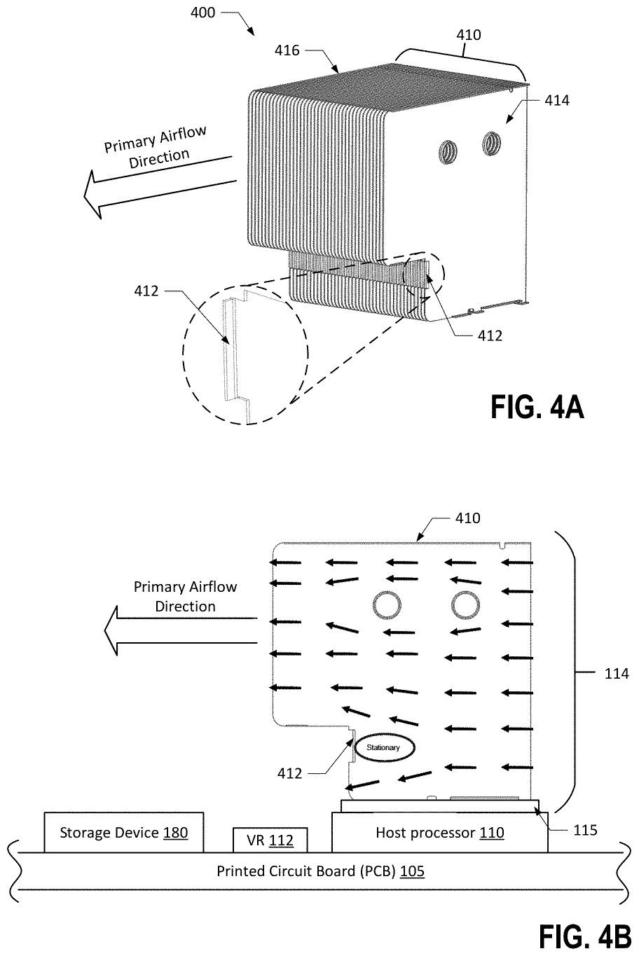

FIGS. 4A-4B illustrates another embodiment of a fin structure 400 having a plurality of fins. A side perspective view of the completed fin structure 400 is shown in FIG. 4A. In FIG. 4B, a single fin within fin structure 400 is shown mounted onto a heat sink 115, which is thermally coupled to a host processor 110 mounted onto a printed circuit board (PCB) 105 (such as a system motherboard). As described in more detail below, a majority of the fins within fin structure 400 include at least one integrated airflow guiding structure for redirecting a portion of the air flowing through the fin structure to one or more heat generating components, which are mounted onto the PCB 105 in the vicinity of the host processor 110. In some embodiments, an active cooling component 116 (such as a fan) may be coupled to (or mounted near) the heat sink 115 and fin structure 400 to increase airflow velocity through the fin structure and improve heat dissipation.

Like the previous embodiment shown in FIGS. 2A-2B, fin structure 400 includes a plurality of fins, which are arranged parallel to one another and stacked together to form a stacked fin structure. A majority of the fins 410 include at least one integrated airflow guiding structure 412, which is formed on an egress side of the fin structure 400 where the airflow exits the fin structure. A first fin 414 and a last fin 416, which are coupled to the fins 410, are formed without an integrated airflow guiding structure 412 to prevent airflow from leaking from the sides of the fin structure 400.

In the embodiment shown in FIGS. 4A-4B, the integrated airflow guiding structure 412 is formed within a lower portion of each fin 410 on the egress side of the fin. In some embodiments, the lower portion of the fins 410 may be narrower than an upper portion of the fins 410 to avoid interference with nearby system components. As noted above, however, the fin geometry is not strictly limited to the particular configuration shown in FIG. 4A and may be configured differently in other embodiments. In some embodiments, for example, the upper and lower portions may have substantially uniform width, and the lower portion may simply be defined as residing within a lower half of the fins 410.

In some embodiments, an integrated airflow guiding structure 412 may be created within each fin 410 by forming a substantially rectangular shaped tab 411 within the lower portion of the fin on the egress side, and bending the tab inward to form a divider. In some embodiments, the substantially rectangular shaped tab 411 is formed substantially parallel to the egress side of each fin 410, so that once bent inward approximately 90°, an integrated airflow guiding structure 412 (or divider) is formed substantially perpendicular to the primary airflow direction.

The length and width of integrated airflow guiding structure 412 (or divider) may generally be chosen based on fin configuration, fin spacing and thermal design needs. In some embodiments, the length of the integrated airflow guiding structure 412 may be generally dependent on thermal design needs, and the width of the integrated airflow guiding structure 412 may depend on the spacing or pitch between the fins 410. In one example embodiment, integrated airflow guiding structure 412 may have a length ranging between about 8.0 mm and about 9.0 mm, and a width ranging between about 0.6 mm and about 0.8 mm. Other dimensions may be used in fin structures having alternative fin geometry and/or spacing.

Although examples are provided herein for illustrative purposes, the dimensions of the integrated airflow guiding structure 412, as well as the placement of the structure along the egress side of the fins 410, are not so strictly limited. Instead, the dimensions and placement of the integrated airflow guiding structure 412 may be chosen to redirect airflow, as needed, to meet thermal design limits specified for the host processor 110 and/or nearby heat generating component(s).

As air flows through the fin structure 400, the integrated airflow guiding structure 412 (or divider) divides the airflow between the primary airflow direction and a secondary airflow direction. In the embodiment shown in FIGS. 4A-4B, the portion of the air flowing in the secondary airflow direction provides a cooling effect to one or more heat generating components, which are mounted to PCB 105 in the vicinity of the host processor 110.

VR 112 and computer readable storage device 180 are illustrated in FIG. 4B as examples of heat generating components that benefit from the cooling effect provided by fin structure. However, fin structure 400 is not limited to cooling any particular component, and may be alternatively used to redirect airflow and provide a cooling effect to other heat generating components arranged within the vicinity of host processor 110. In some embodiments, an active cooling component 116 (such as a fan) may be coupled to (or mounted near) an ingress side of fin structure 400 to increase airflow velocity through the fin structure, improve heat dissipation away from host processor 110 and improve thermal characteristics of nearby heat generating components.

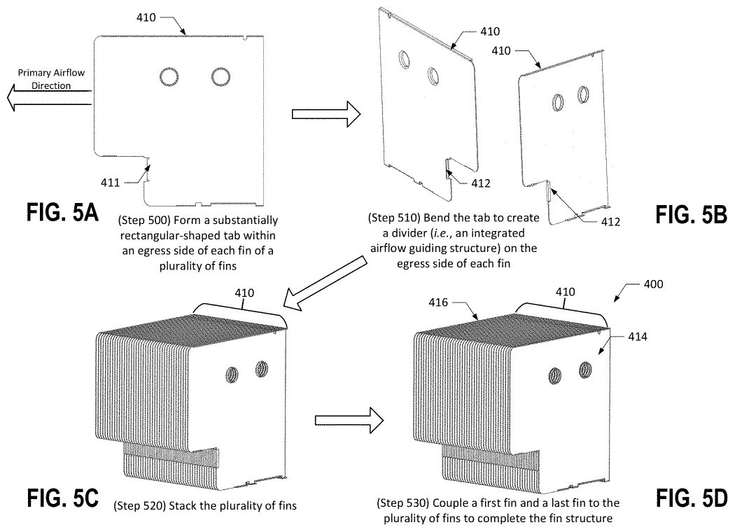

FIGS. 5A-5D illustrate one embodiment of a method that may be used to form the fin structure 400 shown in FIG. 4A. As noted above, fin structure 400 includes a plurality of fins, which are stacked together to form a stacked fin structure. In some embodiments, the method may begin (in step 500) by forming a substantially rectangular shaped tab 411 within an egress side of each individual fin 410. In the embodiment shown in FIG. 5A, a substantially rectangular shaped tab 411 is formed (e.g., cut) within a lower portion of each fin 410, on the egress side of the fin. In other embodiments, the substantially rectangular shaped tab 411 may be formed anywhere along the egress side of the fin 410, as discussed above.

In order to redirect airflow in a substantially downward direction, the substantially rectangular shaped tab 411 may be formed substantially parallel to the egress edge of the fin 410. As noted above, the length of the substantially rectangular shaped tab 411 may be generally dependent on thermal design needs, and the width may depend on the spacing or pitch between fins 410. In one embodiment, the substantially rectangular shaped tab 411 may have a length ranging between 7.5 mm and 8.5 mm, and a width ranging between 0.6 mm and 0.8 mm. However, the length and width of the substantially rectangular shaped tab 411 is not restricted to the example ranges provided above may be chosen based on fin configuration, fin spacing and thermal design needs.

In step 510, the substantially rectangular shaped tab 411 is bent to create an integrated air guiding structure (or divider) 412 on the egress side of each fin 410. In some embodiments, the substantially rectangular shaped tab 411 may be bent inward approximately 90° to form an integrated airflow guiding structure (or divider) 412 within each fin 410, as shown in FIG. 5B. Once an integrated airflow guiding structure (or divider) 112 is formed within each fin 410, the plurality of fins 410 may be stacked together (in step 520), as shown in FIG. 5C. A first fin 414 and a last fin 416 may then be coupled to opposing sides of the stacked plurality of fins 410 to complete the fin structure 400 (in step 530), as shown in FIG. 5D. As noted above, the first and last fins 414, 416 are preferably formed without an integrated airflow guiding structure 412 to prevent airflow from leaking from the sides of the fin structure 400.

While the invention may be adaptable to various modifications and alternative forms, specific embodiments have been shown by way of example and described herein. However, it should be understood that the invention is not intended to be limited to the particular forms disclosed. Rather, the invention is to cover all modifications, equivalents, and alternatives falling within the spirit and scope of the invention as defined by the appended claims. Moreover, the different aspects of the disclosed systems and methods may be utilized in various combinations and/or independently. Thus, the invention is not limited to only those combinations shown herein, but rather may include other combinations.

What is claimed is:

1. A fin structure, comprising:
a plurality of fins arranged parallel to one another and configured to dissipate thermal energy, which is generated by a heat generating component and conducted by a heat sink to the fin structure via convection, wherein air flows through the plurality of fins in a primary airflow direction; and
at least one structure integrated within each of the plurality of fins and configured to redirect a portion of the airflow in a direction, which differs from the primary airflow direction.

2. The fin structure as recited in claim 1, wherein the at least one structure is formed anywhere along an egress side of each of the plurality of fins where the airflow exits the fin structure.

3. The fin structure as recited in claim 2, wherein the at least one structure is formed within a lower portion of each of the plurality of fins on the egress side.

4. The fin structure as recited in claim 2, wherein the at least one structure is formed by cutting a substantially rectangular shaped tab within each of the plurality of fins on the egress side, and bending the tab inward.

5. The fin structure as recited in claim 4, wherein the substantially rectangular shaped tab is formed within each of the plurality of fins at an angle approximately −75° to 75° from the primary airflow direction, and bent inward to form a baffle.

6. The fin structure as recited in claim 5, wherein the baffle captures the portion of the airflow and redirects the captured portion in a substantially downward direction toward one or more heat generating components arranged in a vicinity of the heat generating component.

7. The fin structure as recited in claim 4, wherein the substantially rectangular shaped tab is formed substantially parallel to the egress side of each of the plurality of fins, and bent inward to form a divider, which is substantially perpendicular to the primary airflow direction.

8. The fin structure as recited in claim 7, wherein the divider divides the airflow between the primary airflow direction and a secondary airflow direction, and wherein the portion of the airflow in the secondary airflow direction provides a cooling effect to one or more heat generating components arranged in a vicinity of the heat generating component.

9. An information handling system, comprising:
a heat generating component;
a heat sink thermally coupled to the heat generating component for conducting heat generated by the heat generating component;
a fin structure thermally coupled to the heat sink for dissipating the heat conducted by the heat sink via convection or radiation into a lower temperature region surrounding the heat generating component, wherein the fin structure comprises:
a plurality of fins arranged parallel to one another, wherein air flows through the plurality of fins in a primary airflow direction; and
at least one structure integrated within each of the plurality of fins, wherein the at least one structure is configured to redirect a portion of the airflow in a direction, which differs from the primary airflow direction.

10. The information handling system as recited in claim 9, further comprising one or more active cooling components coupled to, or mounted near, the heat sink and the fin structure to increase airflow velocity through the fin structure and improve heat dissipation.

11. The information handling system as recited in claim 9, wherein the at least one structure is formed anywhere along an egress side of each of the plurality of fins where the airflow exits the fin structure.

12. The information handling system as recited in claim 11, wherein the at least one structure is formed within a lower portion of each of the plurality of fins on the egress side.

13. The information handling system as recited in claim 11, wherein the at least one structure is formed by cutting a substantially rectangular shaped tab within each of the plurality of fins on the egress side, and bending the tab inward.

14. The information handling system as recited in claim 13, wherein the substantially rectangular shaped tab is formed within each of the plurality of fins at an angle approximately −75° to 75° from the primary airflow direction, and bent inward to form a baffle.

15. The information handling system as recited in claim 14, wherein the baffle captures the portion of the airflow and redirects the captured portion in a substantially downward direction toward one or more heat generating components arranged in a vicinity of the heat generating component.

16. The information handling system as recited in claim 13, wherein the substantially rectangular shaped tab is formed substantially parallel to the egress side of each of the plurality of fins, and bent inward to form a divider, which is substantially perpendicular to the primary airflow direction.

17. The information handling system as recited in claim 16, wherein the divider divides the airflow between the primary airflow direction and a secondary airflow direction, and wherein airflow in the secondary airflow direction provides a cooling effect to one or more heat generating components arranged in a vicinity of the heat generating component.

18. A method to form a stacked fin structure including a plurality of fins, the method comprising:
forming a substantially rectangular shaped tab within an egress side of each of the plurality of fins;
bending the substantially rectangular shaped tab inward to create an integrated air guiding structure on the egress side of each fin;
stacking the plurality of fins together; and
coupling a first fin and a last fin to opposing sides of the stacked plurality of fins to complete the stacked fin structure.

19. The method as recited in claim 18, wherein once completed, the stacked fin structure is configured to dissipate thermal energy via airflow through the plurality of fins in a primary airflow direction, and wherein:
the integrated airflow guiding structure redirects a portion of the airflow in a direction, which differs from the primary airflow direction; and
the first fin and the last fin do not include the integrated air guiding structure to prevent air leakage from sides of the stacked fin structure.

20. The method as recited in claim 19, wherein said forming comprises forming the substantially rectangular shaped tab at an angle approximately −75° to 75° from the primary airflow direction, and wherein said bending comprises bending the substantially rectangular shaped tab inward to form a baffle, which captures the portion of the airflow and redirects the captured portion in a substantially downward direction.

21. The method as recited in claim 19, wherein said forming comprises forming the substantially rectangular shaped tab substantially parallel to the egress side of each of the plurality of fins, and wherein said bending comprises bending the substantially rectangular shaped tab inward to form a divider, which is substantially perpendicular to the primary airflow direction.
